(19) United States
(12) Patent Application Publication
(10) Pub. No.: US 2013/0234332 A1
(43) Pub. Date: Sep. 12, 2013

(54) SEMICONDUCTOR DEVICE AND METHOD FOR MANUFACTURING THE SAME

(71) Applicants: Hiromitsu IINO, Mie-ken (JP); Tadashi IGUCHI, Mie-ken (JP)

(72) Inventors: Hiromitsu IINO, Mie-ken (JP); Tadashi IGUCHI, Mie-ken (JP)

(73) Assignee: Kabushiki Kaisha Toshiba, Tokyo (JP)

(21) Appl. No.: 13/600,439

(22) Filed: Aug. 31, 2012

(30) Foreign Application Priority Data
Mar. 7, 2012 (JP) 2012-051026

(51) Int. Cl. H01L 23/48; H01L 21/48

(52) U.S. Cl. CPC H01L 23/481; H01L 21/486
USPC 257/751; 438/637

(57) ABSTRACT

According to one embodiment, a semiconductor device includes a stacked body in which a plurality of conductive layers and a plurality of insulating layers are alternately stacked. The semiconductor device includes a plurality of contact electrodes, a plurality of first insulating portions, and a plurality of second insulating portions. The plurality of contact electrodes extends in a stacking direction of the stacked body. Each of the contact electrodes reaches corresponding one of the conductive layers. The plurality of first insulating portions respectively is provided between the plurality of contact electrodes and the stacked body. The plurality of second insulating portions respectively is provided between the plurality of first insulating portions and the stacked body.

### CROSS-REFERENCE TO RELATED APPLICATIONS

This application is based upon and claims the benefit of priority from the prior Japanese Patent Application No. 2012-051026, filed on Mar. 7, 2012; the entire contents of which are incorporated herein by reference.

### FIELD

Embodiments described herein relate generally to a semiconductor device and a method for manufacturing the same.

### BACKGROUND

There is a semiconductor device including a stacked body in which a plurality of conductive layers and a plurality of insulating layers are alternately stacked.

In such a semiconductor device, the stacked conductive layers are processed in a stepwise manner in order to connect each of the plurality of stacked conductive layers to an upper layer wiring. That is, the conductive layers are processed in such a way as to become longer toward a lower layer at a region where each of the plurality of stacked conductive layers is connected to the upper layer wiring.

However, it is difficult to accurately process the stacked conductive layers in the stepwise manner, and there is a concern of decreasing productivity.

### BRIEF DESCRIPTION OF THE DRAWINGS

FIG. 1 is a schematic perspective view for illustrating a configuration of the element region 1a provided in the semiconductor device 1 according to the first embodiment;

FIG. 2 is a schematic view for illustrating a cross-section of a portion where the silicon body 20 penetrates the conductive layers WL1 to WL4 and the insulating layers 25 between the conductive layers;

FIG. 3 is a schematic cross-sectional view for illustrating a configuration of the contact region 1b provided in the semiconductor device 1 according to the first embodiment;

FIG. 4 is schematic process cross-sectional view for illustrating the formation of the elements provided in the contact region 1b;

FIGS. 5A to 5C are schematic process cross-sectional views for illustrating the formation of the elements provided in the contact region 1b;

FIGS. 6A and 6B are schematic process cross-sectional views for illustrating the formation of the elements provided in the contact region 1b;

FIGS. 7A and 7B are schematic process cross-sectional views for illustrating the formation of the elements provided in the contact region 1b;

FIGS. 8A and 8B are schematic process cross-sectional views for illustrating formation of the frame portion 61f and the contact electrode 60f in the peripheral circuit region 1c; and

FIG. 9 is a schematic perspective view for illustrating a configuration of an element region 1a1 provided in the semiconductor device 1 according to the first embodiment.

### DETAILED DESCRIPTION

In general, according to one embodiment, a semiconductor device includes a stacked body in which a plurality of conductive layers and a plurality of insulating layers are alternately stacked. The semiconductor device includes a plurality of contact electrodes, a plurality of first insulating portions, and a plurality of second insulating portions. The plurality of contact electrodes extends in a stacking direction of the stacked body. Each of the contact electrodes reaches corresponding one of the conductive layers. The plurality of first insulating portions respectively is provided between the plurality of contact electrodes and the stacked body. The plurality of second insulating portions respectively is provided between the plurality of first insulating portions and the stacked body.

Hereinafter, embodiments will be illustrated with reference to the drawings. Note that, in each of the drawings, similar configuration elements will be denoted with the same reference numerals and detailed description is properly omitted.

Also, an XYZ rectangular coordinate system is herein introduced for convenience of description. In this coordinate system, two directions parallel to a main surface of a substrate 10 and orthogonal to each other are defined as an X direction and a Y direction, and a direction orthogonal to both the X and Y directions is defined as a Z direction.

Although a silicon semiconductor is illustrated in the following embodiments, semiconductors other than the silicon semiconductor may be used.

### First Embodiment

First, a semiconductor device 1 according to a first embodiment will be illustrated.

The semiconductor device 1 according to the first embodiment includes an element region 1a and a contact region 1b. The element region 1a is a region where a semiconductor element is provided, and the contact region 1b is a region where a contact electrode for connecting a conductive layer to an upper layer wiring is provided.

Note that, a known technology can be applied to a peripheral circuit region where a peripheral circuit for driving the semiconductor element (memory cell) provided in the element region 1a is provided, the upper layer wiring, and the like, and therefore description is omitted.

First, a configuration of the element region 1a will be illustrated.

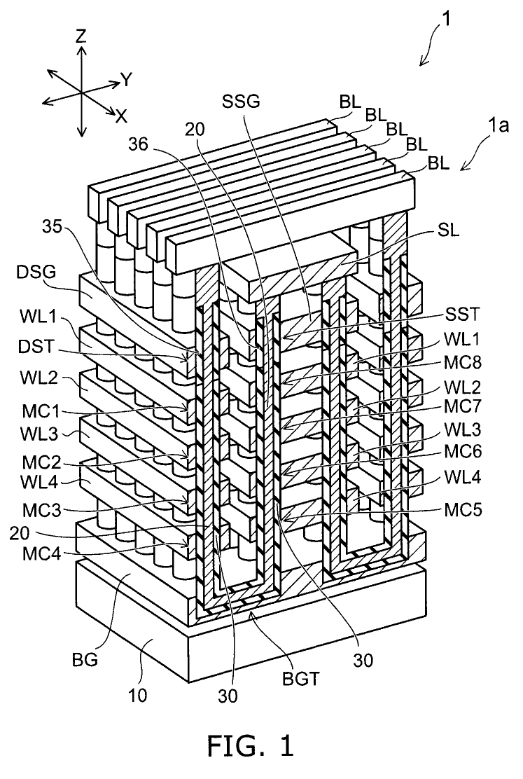

FIG. 1 is a schematic perspective view for illustrating a configuration of the element region 1a provided in the semiconductor device 1 according to the first embodiment.

FIG. 1 illustrates a configuration of a memory cell array provided in the element region 1a, as an example.

Note that, in FIG. 1, for purpose of easily viewing the drawing, illustration of insulating portions other than an insulating film formed inside a memory hole is omitted.

As shown in FIG. 1, a back gate BG is provided above the substrate 10 via an insulating layer (not shown). The back gate BG is, for example, a silicon layer doped with an impurity and having conductivity. A plurality of conductive layers WL1 to WL4 and a plurality of insulating layers (not shown) are alternately stacked on the back gate BG. The number of the conductive layers WL1 to WL4 can be arbitrarily determined and, for example, a case of four layers will be illustrated in the embodiment. The conductive layers WL1 to WL4 are, for example, silicon layers doped with an impurity and having conductivity.

The conductive layers WL1 to WL4 are divided into a plurality of blocks by grooves extending in the X direction. A drain-side selection gate DSG is provided above the uppermost conductive layer WL1 of a certain block via an insulating layer (not shown). The drain-side selection gate DSG is, for example, a silicon layer doped with an impurity and having conductivity. A source-side selection gate SSG is provided, via an insulating layer (not shown), above the uppermost conductive layer WL1 of another block adjacent to the block of the drain-side selection gate DSG. The source-side selection gate SSG is, for example, a silicon layer doped with an impurity and having conductivity.

A source line SL is provided above the source-side selection gate SSG via an insulating layer (not shown). The source line SL is, for example, a silicon layer doped with an impurity and having conductivity. Alternatively, the source line SL may be made of a metal material. A plurality of bit lines BL is provided above the source line SL and the drain-side selection gate DSG via an insulating layer (not shown). Each of the bit lines BL extends in the Y direction.

A plurality of U-shaped memory holes is formed in the above-described stacked body on the substrate 10. The memory hole is formed in the block which includes the drain-side selection gate DSG, the memory hole penetrating the drain-side selection gate DSG and the conductive layers WL1 to WL4 under the drain-side selection gate DSG and extending in the Z direction. Further, the memory hole is formed in the block which includes the source-side selection gate SSG, the memory hole penetrating the source-side selection gate SSG and the conductive layers WL1 to WL4 under the source-side selection gate SSG and extending in the Z direction. The both memory holes are mutually connected via the memory hole formed inside the back gate BG and extending in the Y direction.

A silicon body 20 serving as a U-shaped semiconductor layer is provided inside the memory hole. A gate insulating film 35 is formed on an inner surface of the memory hole between the drain-side selection gate DSG and the silicon body 20. A gate insulating film 36 is formed on an inner surface of the memory hole between the source-side selection gate SSG and the silicon body 20. An insulating film 30 is formed on an inner surface of the memory hole between each of the conductive layers WL1 to WL4 and the silicon body 20. The insulating film 30 is also formed on an inner surface of the memory hole between the back gate BG and the silicon body 20. The insulating film 30 has an oxide-nitride-oxide (ONO) structure in which a silicon nitride film is placed between a pair of silicon oxide films, for example.

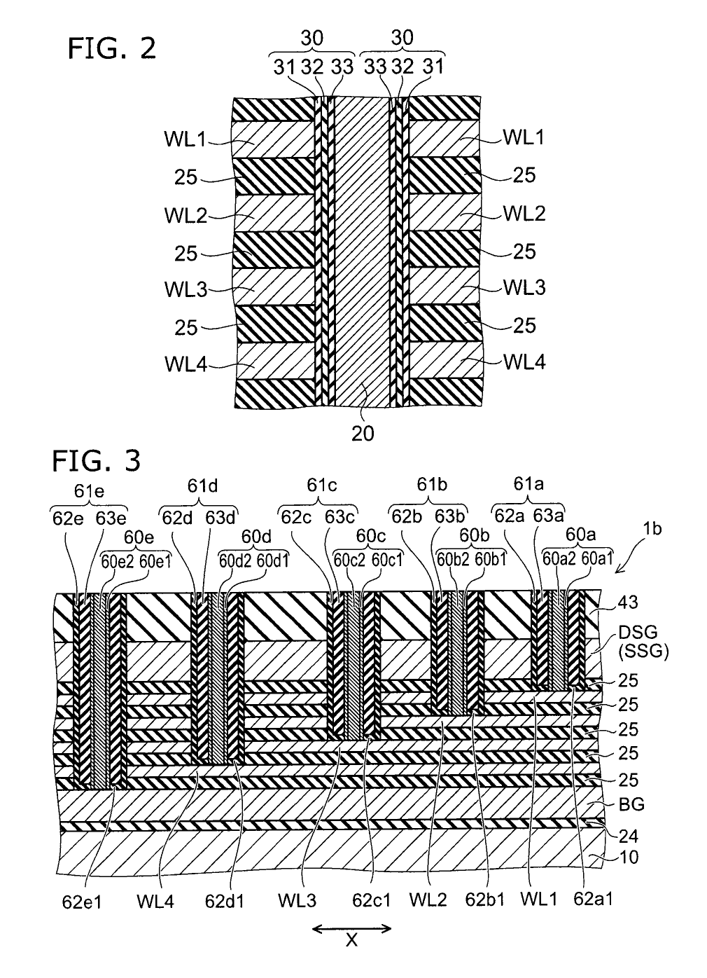

FIG. 2 is a schematic view for illustrating a cross-section of a portion where the silicon body 20 penetrates the conductive layers WL1 to WL4 and the insulating layers 25 between the conductive layers.

A first insulating film 31, a charge storage layer 32, and a second insulating film 33 are provided between the conductive layers WL1 to WL4 and the silicon body 20 in this order from the side of the conductive layers WL1 to WL4. The first insulating film 31 is in contact with the conductive layers WL1 to WL4, the second insulating film 33 is in contact with the silicon body 20, and the charge storage layer 32 is provided between the first insulating film 31 and the second insulating film 33.

The silicon body 20 functions as a channel, the conductive layers WL1 to WL4 function as control gates, and the charge storage layer 32 functions as a data memory layer for storing charges injected from the silicon body 20. That is, a memory cell having a structure in which the control gate surrounds a periphery of the channel is formed at an intersection of the silicon body 20 and each of the conductive layers WL1 to WL4.

The semiconductor device 1 is a nonvolatile semiconductor memory device which is capable of electrically freely writing/erasing data, and retaining stored contents even when the power is turned off. The memory cell is, for example, a memory cell of a charge trap structure. The charge storage layer 32 has a large number of traps that confine charges (electrons), and is made of a silicon nitride film, for example. The second insulating film 33 is, for example, made of a silicon oxide film, and serves as a potential barrier when the charges are injected from the silicon body 20 to the charge storage layer 32, or when the charges stored in the charge storage layer 32 diffuse into the silicon body 20. The first insulating film 31 is, for example, made of a silicon oxide film, and prevents the charges stored in the charge storage layer 32 from diffusing into the conductive layers WL1 to WL4.

Referring back to FIG. 1, the gate insulating film 35 is provided between the drain-side selection gate DSG and the silicon body 20 which penetrates the drain-side selection gate DSG. The gate insulating film 35, the drain-side selection gate DSG, and the silicon body 20 constitute a drain-side selection transistor DST. An upper end portion of the silicon body 20 protruding upward from the drain-side selection gate DSG is connected to a corresponding bit line BL.

The gate insulating film 36 is provided between the source-side selection gate SSG and the silicon body 20 which penetrates the source-side selection gate SSG. The gate insulating film 36, the source-side selection gate SSG, and the silicon body 20 constitute a source-side selection transistor SST. An upper end portion of the silicon body 20 protruding upward from the source-side selection gate SSG is connected to the source line SL.

The back gate BG, the silicon body 20 provided in the back gate BG, and the insulating film 30 between the back gate BG and the silicon body 20 constitute a back gate transistor BGT.

A memory cell MC1 having the conductive layer WL1 as the control gate, a memory cell MC2 having the conductive layer WL2 as the control gate, a memory cell MC3 having the conductive layer WL3 as the control gate, and a memory cell MC4 having the conductive layer WL4 as the control gate are provided between the drain-side selection transistor DST and the back gate transistor BGT.

A memory cell MC5 having the conductive layer WL4 as the control gate, a memory cell MC6 having the conductive layer WL3 as the control gate, a memory cell MC7 having the conductive layer WL2 as the control gate, and a memory cell MC8 having the conductive layer WL1 as the control gate are provided between the back gate transistor BGT and the source-side selection transistor SST.

The drain-side selection transistor DST, the memory cells MC1 to MC4, the back gate transistor BGT, the memory cells MC5 to MC8, and the source-side selection transistor SST are connected in series to constitute one memory string. A plurality of such memory strings is arranged in the X and Y directions, whereby the plurality of memory cells MC1 to MC8 is three-dimensionally provided in the X, Y and Z directions.

Next, the contact region 1b will be illustrated.

FIG. 3 is a schematic cross-sectional view for illustrating a configuration of the contact region 1b provided in the semiconductor device 1 according to the first embodiment.

The contact region 1b is contiguously provided to the element region 1a shown in FIG. 1 in the X direction. Further, the back gate BG is provided above the substrate 10 via an insulating layer 24, and the plurality of conductive layers WL1 to WL4 and the plurality of insulating layers 25 are alternately stacked on the back gate BG in the contact region 1b in a similar manner to the element region 1a. Note that, in FIG. 3, an insulating layer between the substrate 10 and the back gate BG is shown as the insulating layer 24, an insulating layer between the conductive layers is shown as the insulating layer 25, and an insulating layer provided on the drain-side selection gate DSG and the source-side selection gate SSG is shown as an insulating layer 43, illustration of the above insulating layers having been omitted in FIG. 1. The insulating layers 24, 25, and 43 can be, for example, formed of silicon oxide.

An upper surface of the insulating layer 43 is flattened, and an upper layer wiring (not shown) and the like which are connected to contact electrodes 60a to 60e are provided on the upper surface.

The contact electrodes 60a to 60e are provided in the contact region 1b. The contact electrodes 60a to 60e extend in a stacking direction of the stacked body (Z direction), and each of the contact electrodes 60a to 60e reaches corresponding one of the conductive layers WL1 to WL4 and the back gate BG.

As the material for the contact electrodes 60a to 60e, for example, a barrier metal having excellent adhesion properties such as titanium or titanium nitride, and a metal having excellent embedding properties such as tungsten, copper, or ruthenium can be used in combination. For example, portions 60a1 to 60e1 using the barrier metal are formed on inner surfaces of first insulating portions 63a to 63e, and portions 60a2 to 60e2 using the metal such as tungsten are embedded in interiors formed by the portions 60a1 to 60e1, thereby serving as the contact electrodes 60a to 60e.

The conductive layers WL1 to WL4 are respectively connected, via the contact electrodes 60a to 60d, to an upper layer wiring (not shown), and the back gate BG is connected to an upper layer wiring (not shown) via the contact electrode 60e. Note that, the drain-side selection gate DSG and the source-side selection gate SSG are also connected to an upper layer wiring (not shown) via contact electrodes (not shown).

Frame portions 61a to 61e are provided in such a way as to cover the contact electrodes 60a to 60e. The frame portions 61a to 61e are provided with the first insulating portions 63a to 63e and second insulating portions 62a to 62e.

The first insulating portions 63a to 63e are provided between the contact electrodes 60a to 60e and the stacked body. The first insulating portions 63a to 63e are provided in such a way as to fill a space between the second insulating portions 62a to 62e and the contact electrodes 60a to 60e.

The second insulating portions 62a to 62e are provided between the first insulating portions 63a to 63e and the stacked body. The second insulating portions 62a to 62e have cylindrical shapes with bottoms, and bottom surfaces 62a1 to 62d1 are in contact with the respective conductive layers WL1 to WL4. A bottom surface 62e1 is in contact with the back gate BG.

The contact electrodes 60a to 60d penetrate the respective bottom surfaces 62a1 to 62d1 of the second insulating portions 62a to 62d, and reach the respective conductive layers WL1 to WL4. The contact electrode 60e penetrates the bottom surface 62e1 of the second insulating portion 62e, and reaches the back gate BG.

The first insulating portions 63a to 63e and the second insulating portions 62a to 62e are formed of the material having insulation properties.

In this case, an etching rate of the material for the second insulating portions 62a to 62e is lower than that of the material for the first insulating portions 63a to 63e. For example, the second insulating portions 62a to 62e are formed of silicon nitride, and the first insulating portions 63a to 63e are formed of silicon oxide.

Note that FIG. 3 illustrates a case where the frame portions 61a to 61e have an approximately constant section size from upper end portions to bottom portions. However, the section size is not limited to this case. For example, the frame portions 61a to 61e may have an inverted circular truncated cone shape in which the section size decreases gradually from the upper end portion to the bottom portion, or may have a step by changing the section size between the upper end portion and the bottom portion.

According to the semiconductor device 1 of the embodiment, it is not necessary to process the conductive layers WL1 to WL4 provided in the contact region 1b in a stepwise manner, whereby improvement of productivity can be achieved.

Further, it is not necessary to process the conductive layers WL1 to WL4 provided in the contact region 1b in the stepwise manner, whereby downsizing of the semiconductor device 1 can be achieved.

Furthermore, if the conductive layers WL1 to WL4 are processed in the stepwise manner, the contact electrodes 60a to 60d can be only provided at a portion (stepped portion) protruding from an upper conductive layer. However, according to the semiconductor device 1 of the embodiment, positions where the contact electrodes 60a to 60d are provided can be freely arranged. For example, the contact electrode 60a having a short length can be provided closer to the element region 1a than the other electrodes or, in contrast, the contact electrode 60d or the contact electrode 60e having long lengths can be provided closer to the element region 1a than the other electrodes.

Furthermore, since the frame portions 61a to 61e are provided, processing accuracy of lower end positions of the contact electrodes 60a to 60e can be improved.

### Second Embodiment

Next, a method of manufacturing a semiconductor device 1 according to a second embodiment will be illustrated.

As described above, the semiconductor device 1 is provided with an element region 1a, a contact region 1b, a peripheral circuit region (not shown), an upper layer wiring (not shown), and the like. A known technology can be applied to formation of elements provided in a region other than the contact region 1b. Therefore, the formation of the elements provided in the contact region 1b will be herein mainly illustrated.

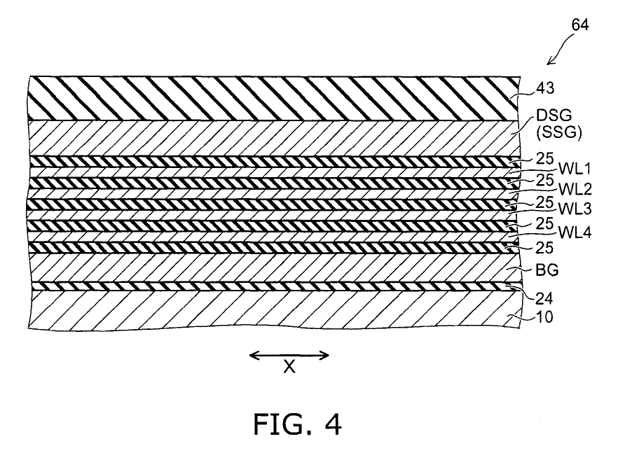

FIGS. 4 to 7 are schematic process cross-sectional views for illustrating the formation of the elements provided in the contact region 1b.

First, as shown in FIG. 4, a stacked body 64 is formed in the following manner. An insulating layer 24 is formed on a substrate 10, a back gate BG is formed on the insulating layer 24, a plurality of insulating layers 25 and a plurality of conductive layers WL1 to WL4 are alternately stacked on the back gate BG, a drain-side selection gate DSG and a source-side selection gate SSG are formed on the stacked layers, and an insulating layer 43 is formed on top of the stacked layers.

In this case, the formation of the stacked body 64 can be performed at both the element region 1a and the contact region 1b simultaneously.

For example, by a chemical vapor deposition (CVD) method, the insulating layer 24 is formed on the substrate 10 shown in FIG. 1, the back gate BG is formed on the insulating layer 24, the plurality of insulating layers 25 and the plurality of conductive layers WL1 to WL4 are stacked on the back gate BG alternately, the drain-side selection gate DSG and the source-side selection gate SSG are formed on the stacked layers, and the insulating layer 43 is formed on top of the stacked layers.

Furthermore, for example, a sacrificial layer may be formed instead of forming the insulating layers 24, 25, and 43. The sacrificial layer is then removed via a memory hole after the memory hole is formed in the element region 1a. The insulating layers 24, 25, and 43 may be formed on the portion where the sacrificial layer has been removed via the memory hole. In this case, the sacrificial layer can be, for example, formed of polysilicon without a doped impurity. A wet etching method using aqueous solution of choline (TMY) or the like can be, for example, used for the removal of the sacrificial layer. An atomic layer deposition (ALD) method or the like can be, for example, used for the formation of the insulating layers 24, 25, and 43.

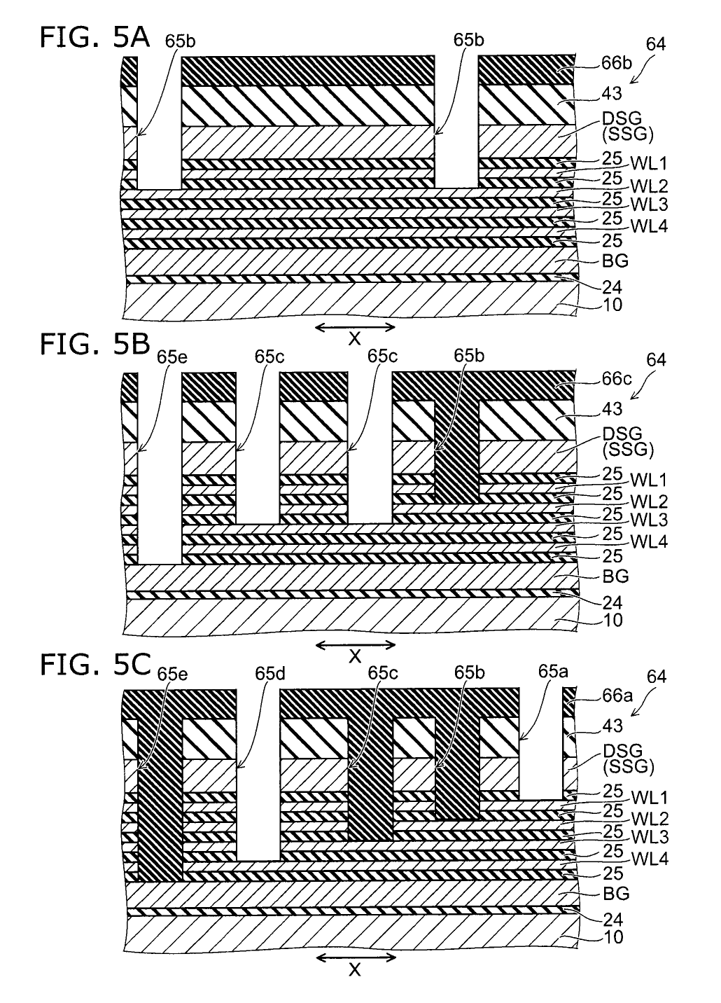

Next, holes 65a to 65e (which correspond to an example of first holes) are formed as shown in FIGS. 5A to 5C in which the frame portions 61a to 61e are formed.

That is, the holes 65a to 65e are formed wherein the holes 65a to 65e extend in the stacking direction of the stacked body 64, and each of the holes 65a to 65e reaches corresponding one of the conductive layers WL1 to WL4 and the back gate BG.

In this case, the holes 65a to 65e having different depths can be formed one by one. However, as shown in FIGS. 5A to 5C, the number of man-hours of processing can be reduced by combining the forming depths.

That is, first, a hole having a first depth is formed. Next, when a hole having a second depth is formed, the formed hole having the first depth is further processed simultaneously.

In this case, a resist mask described later is formed by properly selecting a photomask from among a plurality of photomasks which are prepared in accordance with the forming depths, and performing a photolithography process using the selected photomask. Then, a process at the contact region 1b is performed using the formed resist mask.

For example, first, the hole 65b is formed as shown in FIG. 5A.

In this case, a resist mask 66b having a predetermined opening is formed on the insulating layer 43, and the hole 65b is formed by a reactive ion etching (RIE) method or the like. The hole 65b is also formed in a position where the hole 65e is to be formed. After the formation of the hole 65b, the resist mask 66b is removed by a wet ashing method or the like.

Next, as shown in FIG. 5B, a resist mask 66c having a predetermined opening is formed on the insulating layer 43, and the hole 65c is formed by the RIE method or the like. In this case, the hole 65c is also formed in positions where the holes 65d and 65e are to be formed. Since the hole 65b has already been formed in the position where the hole 65e is to be formed, the hole 65e having a longer depth than the hole 65b can be formed.

That is, the hole 65e can be formed, when the hole 65c is formed, in such a way as to extend the hole 65b which has already been formed. In this case, a step due to misalignment or the like in the photolithography process may occur at a joint portion between the hole 65b which has already been formed and a hole to be newly formed. However, even if such a step occurs, the frame portion 61e can be formed.

After the formation of the hole 65c, the resist mask 66c is removed by the wet ashing method or the like.

Next, as shown in FIG. 5C, a resist mask 66a having a predetermined opening is formed on the insulating layer 43, and the hole 65a is formed by the RIE method or the like. In this case, the hole 65a is also formed in a position where the hole 65d is to be formed. Since the hole 65c has already been formed in the position where the hole 65d is to be formed, the hole 65d having a longer depth than the hole 65c can be formed.

That is, the hole 65d can be formed, when the hole 65a is formed, in such a way as to extend the hole 65c which has already been formed. In this case, a step due to misalignment or the like in the photolithography process may occur at a joint portion between the hole 65c which has already been formed and a hole to be newly formed. However, even if such a step occurs, the frame portion 61d can be formed.

After the formation of the hole 65a, the resist mask 66a is removed by the wet ashing method or the like.

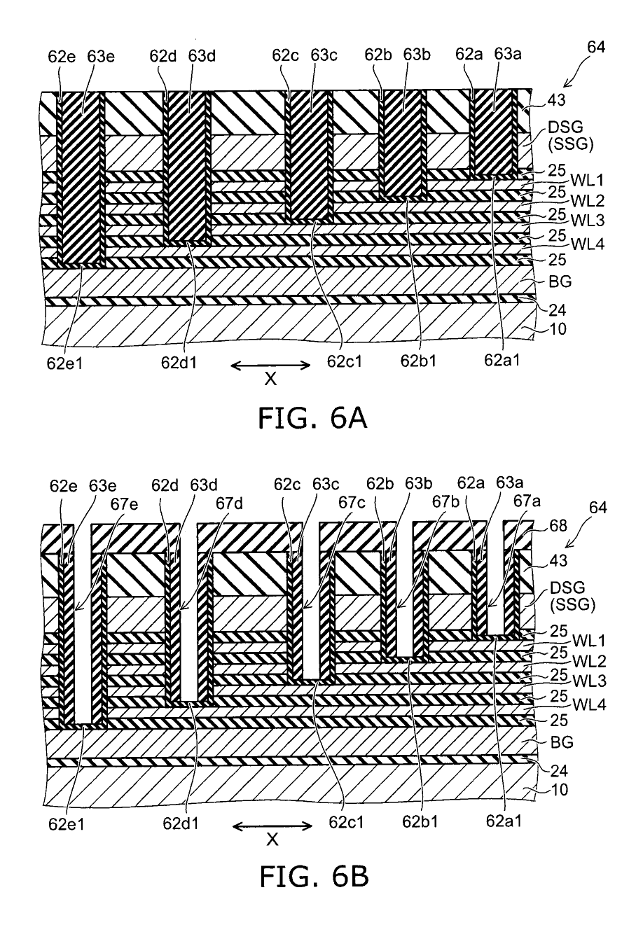

Next, as shown in FIG. 6A, the second insulating portions 62a to 62e are formed on inner surfaces of the holes 65a to 65e. Then, the first insulating portions 63a to 63e are formed in interiors formed by the second insulating portions 62a to 62e. The formation of the second insulating portions 62a to 62e and the first insulating portions 63a to 63e can be, for example, performed by the CVD method or the like.

In this case, the second insulating portions 62a to 62e are formed using the material having a lower etching rate than the material for the first insulating portion 63a to 63e. For example, the second insulating portions 62a to 62e can be formed of silicon nitride, and the first insulating portions 63a to 63e can be formed of silicon oxide.

Next, as shown in FIG. 6B, holes 67a to 67e (which correspond to an example of second holes) are formed in which the contact electrodes 60a to 60e are formed.

That is, the holes 67a to 67e are formed, wherein the holes 67a to 67e extend inside the first insulating portions 63a to 63e in the stacking direction of the stacked body 64, and each of the holes 67a to 67e reaches the corresponding one of conductive layers WL1 to WL4 and the back gate BG.

For example, a resist mask 68 having a predetermined opening is formed on the insulating layer 43, and the holes 67a to 67e are formed by the RIE method or the like.

In this case, the hole 67a having a short depth is formed first, and the bottom surface 62a1 of the second insulating portion 62a will be exposed. However, since the second insulating portions 62a to 62e are formed of the material having the lower etching rate than that of the material for the first insulating portions 63a to 63e, the other holes 67b to 67e are formed before the hole 67a penetrates the bottom surface 62a1 of the second insulating portion 62a. That is, the holes 67a to 67e penetrating the first insulating portions 63a to 63e are formed before the holes 67a to 67e penetrate the bottom surfaces 62a1 to 62e1 of the second insulating portions 62a to 62e.

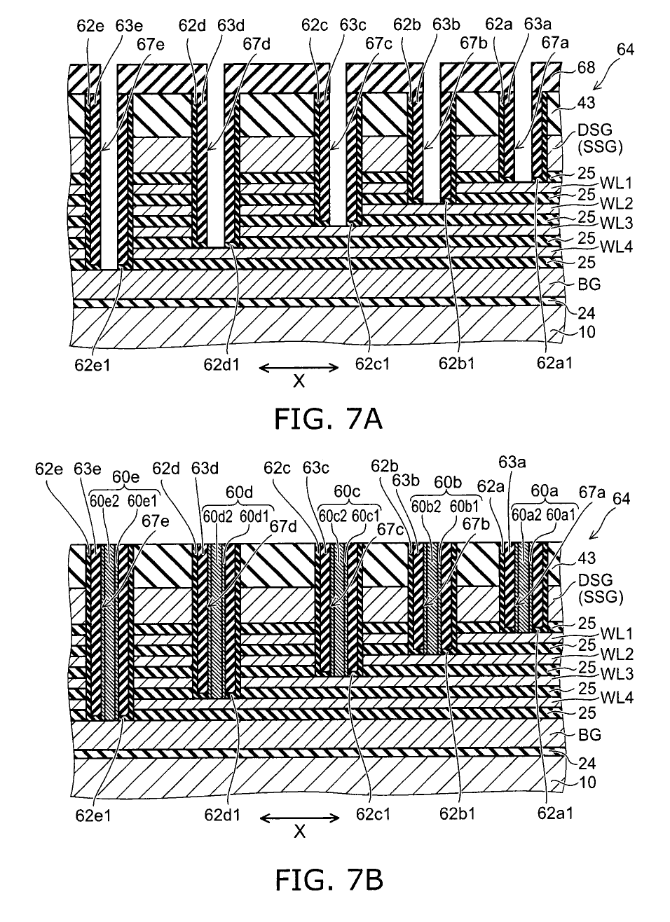

Next, as shown in FIG. 7A, the conductive layers WL1 to WL4 and the back gate BG are respectively exposed by allowing the respective bottom surfaces 62a1 to 62e1 of the second insulating portions 62a to 62e to be penetrated.

The resist mask 68 is then removed by the wet ashing method or the like.

Next, as shown in FIG. 7B, the contact electrodes 60a to 60e are respectively formed in the holes 67a to 67e.

For example, a film serving as the contact electrodes 60a to 60e can be formed in such a way as to cover a surface of the insulating layer 43.

The film formed outside the holes 67a to 67e is then removed, and the contact electrodes 60a to 60e are embedded and formed inside the holes 67a to 67e.

As described above, the elements provided in the contact region 1b can be formed.

Then, an upper layer wiring (not shown) is formed above the insulating layer 43, and the contact electrodes 60a to 60e and the upper layer wiring (not shown) are connected.

In this way, the semiconductor device 1 can be manufactured.

According to the method of manufacturing a semiconductor device of the embodiment, it is not necessary to process the conductive layers WL1 to WL4 provided in the contact region 1b in a stepwise manner, whereby improvement of productivity can be achieved.

Further, it is not necessary to form the conductive layers WL1 to WL4 provided in the contact region 1b in the stepwise manner, whereby downsizing of the semiconductor device 1 can be achieved.

Furthermore, if the conductive layers WL1 to WL4 are processed in the stepwise manner, the contact electrodes 60a to 60d can be only provided at a portion (stepped portion) protruding from a conductive layer of an upper layer. However, according to the method of manufacturing a semiconductor device of the embodiment, positions where the contact electrodes 60a to 60d are provided can be freely arranged. For example, the contact electrode 60a having a short length can be provided closer to the element region 1a than the other electrodes or, in contrast, the contact electrode 60d and the contact electrode 60e having long lengths can be provided closer to the element region 1a than the other electrodes.

Furthermore, since the frame portions 61a to 61e are provided, processing accuracy of lower end positions of the contact electrodes 60a to 60e can be improved.

Here, a peripheral circuit region 1c is also contiguously provided to the element region 1a. Also, a semiconductor element 22 (for example, a transistor) for driving a memory cell provided in the peripheral circuit region 1c is connected to an upper layer wiring (not shown) via a contact electrode 60f.

Therefore, the number of man-hours of processing the peripheral circuit region 1c can be reduced by forming a frame portion 61f and the contact electrode 60f in the peripheral circuit region 1c when the frame portions 61a to 61e and the contact electrodes 60a to 60e are formed in the contact region 1b.

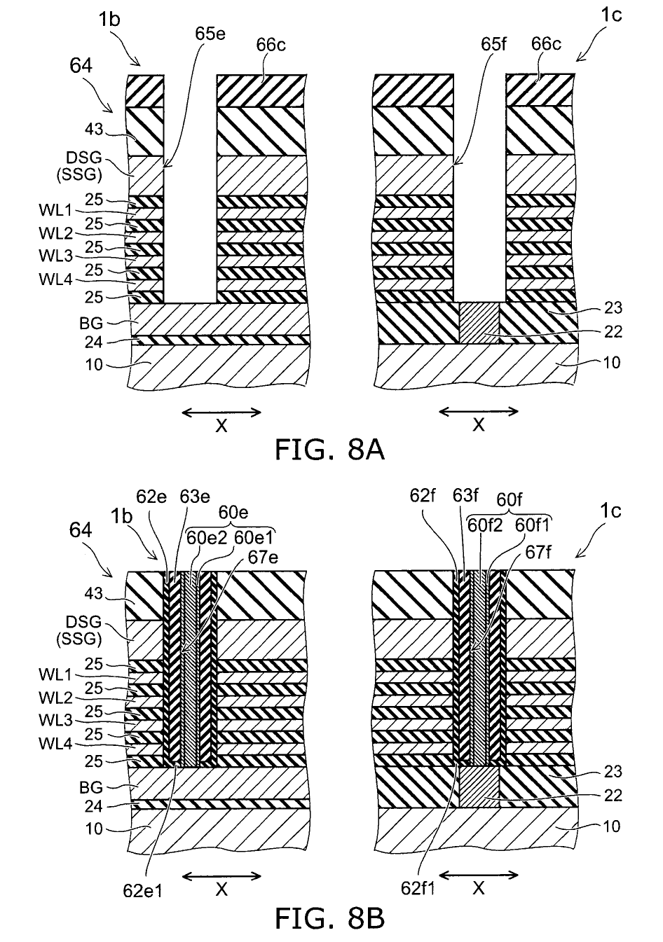

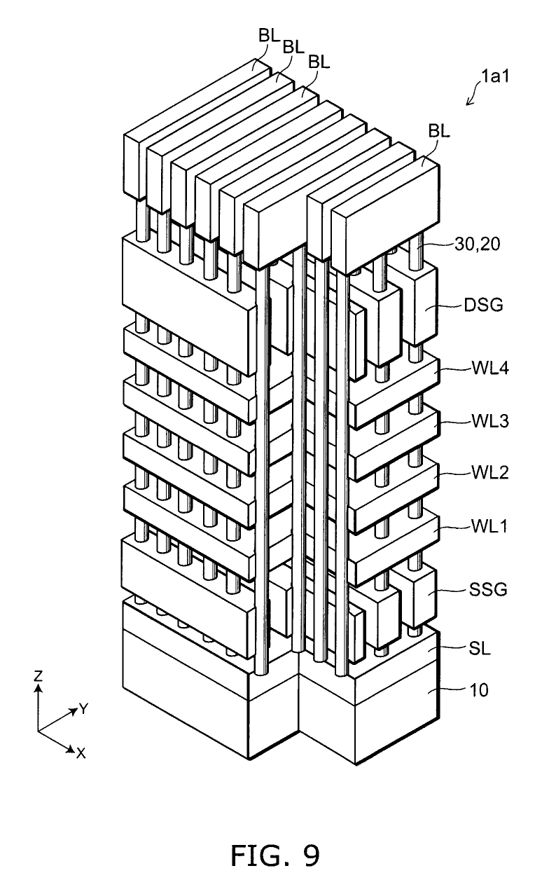

FIGS. 8A and 8B are schematic process cross-sectional views for illustrating formation of the frame portion 61f and the contact electrode 60f in the peripheral circuit region 1c.

First, as shown in FIG. 8A, the hole 65f is formed in the peripheral circuit region 1c when the hole 65e is formed in the contact region 1b. That is, the hole 65f can be formed in a similar manner to the formation of the hole 65e illustrated in FIGS. 5A to 5C.

Next, as shown in FIG. 8B, a second insulating portion 62f is formed when a second insulating portion 62e is formed, a first insulating portion 63f is formed when a first insulating portion 63e is formed, a hole 67f is formed when a hole 67e is formed, a bottom surface 62f1 of the second insulating portion 62f is penetrated when a bottom surface 62e1 of the second insulating portion 62e is penetrated, and the contact electrode 60f is formed when the contact electrode 60e is formed.

That is, the frame portion 61f and the contact electrode 60f can be formed in the peripheral circuit region 1c when the frame portion 61e and the contact electrode 60e are formed in the contact region 1b.

In this case, a portion 60f1 using a barrier metal is formed on an inner surface of the first insulating portion 63f and a portion 60f2 using a metal such as tungsten is embedded in an interior formed by the portion 60f1 in a similar manner to the contact electrode 60e, thereby serving as the contact electrode 60f.

In this way, the number of man-hours of processing the peripheral circuit region 1c can be reduced.

FIG. 9 is a schematic perspective view for illustrating a configuration of an element region 1a1 provided in the semiconductor device 1 according to the first embodiment.

Note that, in FIG. 9, for purpose of easily viewing the drawing, illustration of insulating portions are omitted and only conductive portions are shown.

Although a U-shaped memory string has been illustrated in FIG. 1, an I-shaped memory string can be employed as shown in FIG. 9.

In this structure, a source line SL is provided on a substrate 10, a source-side selection gate SSG (or lower portion selection gate) is provided above the source line SL, conductive layers WL1 to WL4 are provided above the source-side selection gate SSG, and a drain-side selection gate DSG (or upper portion selection gate) is provided between the uppermost conductive layer WL1 and a bit line BL.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A semiconductor device including a stacked body in which a plurality of conductive layers and a plurality of insulating layers are alternately stacked, comprising:
a plurality of contact electrodes extending in a stacking direction of the stacked body, each of the contact electrodes reaching corresponding one of the conductive layers;
a plurality of first insulating portions respectively provided between the plurality of contact electrodes and the stacked body; and
a plurality of second insulating portions respectively provided between the plurality of first insulating portions and the stacked body.

2. The device according to claim 1, wherein
the plurality of second insulating portions has a cylindrical shape with a bottom, and
the plurality of contact electrodes configured to penetrate respective bottom surfaces of the plurality of second insulating portions, and reaches the corresponding conductive layers.

3. The device according to claim 2, wherein the bottom surfaces of the plurality of second insulating portions are respectively in contact with the corresponding conductive layers.

4. The device according to claim 1, wherein a material for the plurality of second insulating portions has a lower etching rate than a material for the plurality of first insulating portions when the plurality of first insulating portions is etched.

5. The device according to claim 1, wherein
the plurality of first insulating portions is formed of silicon oxide, and
the plurality of second insulating portions is formed of silicon nitride.

6. The device according to claim 1, wherein the plurality of first insulating portions and the plurality of second insulating portions have a constant section size from an upper end portion to a bottom portion.

7. The device according to claim 1, wherein the plurality of first insulating portions and the plurality of second insulating portions have a section size gradually decreasing from an upper end portion to a bottom portion.

8. The device according to claim 1, wherein the plurality of first insulating portions and the plurality of second insulating portions form a step by changing a section size between an upper end portion and a bottom portion.

9. The device according to claim 1, wherein each of the plurality of contact electrodes has a portion using a metal, and a portion using a barrier metal and provided between the portion using a metal and the first insulating portion.

10. The device according to claim 9, wherein the portion using a metal includes at least one kind selected from the group consisting of tungsten, copper, and ruthenium.

11. The device according to claim 9, wherein the portion using a barrier metal includes at least one kind of titanium and titanium nitride.

12. A method of manufacturing a semiconductor device, comprising:
forming a stacked body by stacking a plurality of conductive layers and a plurality of insulating layers alternatively;
forming a plurality of first holes extending in a stacking direction of the stacked body, each of the first holes reaching corresponding one of the conductive layers;
respectively forming a plurality of second insulating portions on inner surfaces of the plurality of first holes;
respectively forming a plurality of first insulating portions in interiors formed by the plurality of second insulating portions;
forming a plurality of second holes extending inside the plurality of first insulating portions in the stacking direction of the stacked body, each of the second holes reaching corresponding one of the conductive layers; and
respectively forming a plurality of contact electrodes inside the plurality of second holes.

13. The method according to claim 12, wherein the forming a plurality of first holes extending in a stacking direction of the stacked body, each of the first holes reaching corresponding one of the conductive layers includes
forming a first hole having a first depth, and
further processing the formed first hole having the first depth at a same time when a first hole having a second depth is formed.

14. The method according to claim 12, wherein the forming a plurality of first holes extending in a stacking direction of the stacked body, each of the first holes reaching corresponding one of the conductive layers includes
forming a first hole having a first depth, and
forming a first hole having a second depth longer than the first depth by extending the formed first hole having the first depth.

15. The method according to claim 12, wherein the forming a plurality of first holes extending in a stacking direction of the stacked body, each of the first holes reaching corresponding one of the conductive layers includes
selecting an appropriate photomask from among a plurality of photomasks prepared in accordance with forming depths, and performing a photolithography process using the selected photomask.

16. The method according to claim 12, wherein the respectively forming a plurality of second insulating portions on inner surfaces of the plurality of first holes includes
forming the plurality of second insulating portions using a material having a lower etching rate than a material for the plurality of first insulating portions.

17. The method according to claim 12, wherein in the respectively forming a plurality of second insulating portions on inner surfaces of the plurality of first holes,
the plurality of second insulating portions is formed of silicon nitride.

18. The method according to claim 12, wherein the respectively forming a plurality of contact electrodes inside the plurality of second holes includes
forming a film using a barrier metal on inner surfaces of the plurality of second holes, and embedding a metal into interiors formed by the film using the barrier metal.

19. The method according to claim 18, wherein the metal includes at least one kind selected from the group consisting of tungsten, copper, and ruthenium.

20. The method according to claim 18, wherein the film using a barrier metal includes at least one kind of titanium and titanium nitride.
